(19) United States
(12) Patent Application Publication
(10) Pub. No.: US 2002/0084519 A1
(43) Pub. Date: Jul. 4, 2002

(54) Semiconductor chip stack package and fabrication method thereof

(75) Inventors: Ill-Heung Choi, Chungcheongnam-do (KR); Young-Hee Song, Kyungki-do (KR); Kwan-Jai Lee, Chungcheongnam-do (KR); Hee-Jin Park, Chungcheongnam-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 09/974,376

(22) Filed: Oct. 9, 2001

(30) Foreign Application Priority Data
Dec. 28, 2000 (KR) 2000-83572

(51) Int. Cl. H01L 23/02

(52) U.S. Cl. 257/678

(57) ABSTRACT

A semiconductor chip stack package includes first and second semiconductor chips and a method for manufacturing the same are disclosed. Each chip has an active surface on which a plurality of electrode pads are formed, and a rear surface opposite to the active surface. The rear surfaces of the first and second chips face each other. The chip stack package further includes a single lead frame which has a plurality of leads that are disposed over and attached to the active surface of one of the first and second chips. Each electrode pad of the first and second chips is electrically connected to a corresponding one of the leads.

### BACKGROUND OF THE INVENTION

1. Field of the Invention The present invention relates to the field of a semiconductor integrated circuit device. More particularly, the present invention relates to a semiconductor chip stack package, and a method for manufacturing the same.

2. Description of the Related Art

As is well known in the art, stack packages of various types have been developed and used to increase memory density or to provide multiple functionality by stacking two or more semiconductor chips in various forms or by stacking complete packages themselves. One such conventional chip stack package is illustrated in FIG. 1.

As shown in FIG. 1, semiconductor chips 12a, 12b are stacked up on a die pad 11a of a lead frame 11 with adhesives 13a, 13b. The chips 12a, 12b are then electrically connected to leads 11b of the lead frame 11 through bonding wires 14a, 14b, respectively. Then a package mold body 15 is formed with a mold resin.

The chip stack package 10 in FIG. 1 is applicable to stacks of chips with varying sizes since electrical connection terminals formed on the larger lower chip 12a are not completely covered by the relatively smaller upper chip 12b. For this reason, chips of the same size are not generally found in the chip stack package 10 in FIG. 1.

An exemplary stack package using same-size chips is shown in FIG. 2. The chip stack package 20 in FIG. 2 employs, like the stack package of FIG. 1, a lead frame 21 having a die pad 21a. The same-size chips 22a, 22b are attached to lower and upper surfaces of the die pad 21a with adhesives 23a, 23b. In addition, bonding wires 24a, 24b make electrical connections between the chips 22a, 22b and leads 21b embedded in a package mold body 25 of a mold resin.

This chip stack package 20 can employ the same-type chips of the same size since each chip 22a, 22b is separately disposed either over or under the die pad 21a. On the other hand, the chip stack package 20 illustrated in FIG. 2 has a drawback in that the size of the package 20 is increased due to use of the die pad 21a of relatively greater size than the chip 22a, 22b. Moreover, the chip stack package 20 in FIG. 2 can hardly use a center pad type chip. As is well known in the art, the chips 22a, 22b shown in FIG. 2 include peripheral pads. Particularly, the peripheral pads are electrical connection terminals formed on the periphery of the chip, as opposed to the center pads that are formed in the center of the chip. If the chips include the center pads for the chip stack package of FIG. 2, longer bonding wires are needed and this undesirably reduces reliability.

To overcome the above drawbacks, another chip stack package has been introduced in the art and herein depicted in FIG. 3. The chip stack package 30 in FIG. 3 employs the center pad type chips 32a, 32b by using so-called lead-on-chip (LOC) lead frames 31a,31b. The chips 32a, 32b are arranged back to back, and the respective LOC lead frames 31a, 31b are extended to central portions of upper surfaces of the respective chips 32a, 32b. Then the lead frames 31a, 31b are directly attached to the chips 32a, 32b by adhesive tapes 33a, 33b and electrically coupled to the chips 32a, 32b by bonding wires 34a, 34b. A package mold body 35 is formed with a mold resin.

However, this type of package 30 also has shortcomings. Since the chip stack package 30 in FIG. 3 uses two lead frames 31a, 31b, a process for joining the lead frames 31a, 31b is required. A way of applying pressure directly and mechanically to the lead frame and an alternative way using lasers are both known in the art. These joining techniques not only demand considerable effort and skill, but also tend to increase process difficulties and device failures. Furthermore, the additional processes increase the manufacturing costs.

### SUMMARY OF THE INVENTION

It is, therefore, an object of the present invention to provide a semiconductor chip stack package that uses a single lead frame free from the unreliable joining process described above and a fabrication method thereof.

Another object of the present invention is to provide a semiconductor chip stack package and a fabrication method thereof that can reduce manufacturing cost and increased efficiency by employing existing fabrication processes and equipment used for general semiconductor chip packages.

Still another object of the present invention is to provide a semiconductor chip stack package and a fabrication method thereof that can utilize center pad type chips to prevent degradation in reliability due to the use of long bonding wires.

Still another object of the present invention is to provide a semiconductor chip stack package having an increased memory density.

In the first aspect of the present invention, a semiconductor chip stack package comprises first and second semiconductor chips. Each chip has an active surface on which a plurality of electrode pads are formed, and a rear surface opposite to the active surface. The rear surfaces of the first and second chips face each other. The semiconductor chip stack package further comprises a single lead frame which has a plurality of leads disposed over and attached to the active surface of one of the first and second chips. Each of the electrode pads of the first and second chips is electrically connected to a corresponding one of the leads. In addition, the first and second chips, and inner leads of the lead frame are encapsulated in a package mold body.

In another aspect of the present invention, a semiconductor chip stack package comprises a first and a second semiconductor chip each of which includes an active surface having a plurality of electrode pads formed in the central portion thereof and a rear surface opposite to the active surface. The rear surfaces of the first and second chips face each other. The chip stack package further comprises a package mold body that encapsulates the first and second chips. A lead frame of the chip stack package includes a plurality of leads arranged near both sides of the electrode pads of the first chip. Each of the leads has an inner lead embedded in the package mold body and an outer lead projecting out of the package mold body. The inner leads are attached to the active surface of the first chip.

Furthermore, each of the inner leads may have a first portion attached to the active surface of the first chip, a second portion extended from the first portion to the active surface of the second chip, and a third portion extended from the second portion to the outer lead. Particularly, the third portion may be substantially level with the active surface of the second chip.

According to still another aspect of the present invention, a method for fabricating a semiconductor chip stack package comprises providing a lead frame, a first semiconductor chip, and a second semiconductor chip. The lead frame has a plurality of leads, and each semiconductor chip has an active surface on which a plurality of electrode pads are formed and a rear surface opposite to the active surface. The fabricating method further comprises attaching the first chip to the single lead frame so that the leads are disposed over and attached to the active surface of the first chip, then electrically connecting the electrode pads of the first chip to a corresponding one of the leads of the single lead frame. The method further comprises attaching the second chip to the first chip so that the rear surfaces face each other, then electrically connecting the electrode pads of the second chip to a corresponding one of the leads of the single lead frame. In addition, the method comprises forming a package mold body so that the first and second chips, and inner leads of the lead frame are encapsulated therein.

### BRIEF DESCRIPTION OF THE DRAWINGS

FIG. 1 is a cross-sectional view showing one example of a conventional semiconductor chip stack package.

FIG. 2 is a cross-sectional view showing another example of a conventional semiconductor chip stack package.

FIG. 3 is a cross-sectional view showing the third example of a conventional semiconductor chip stack package.

FIG. 4 is a cross-sectional view showing a semiconductor chip stack package according to one embodiment of the present invention.

FIGS. 5A to 5E are cross-sectional views showing a method for fabricating the semiconductor chip stack package shown in FIG. 4.

FIG. 6 is a cross-sectional view partially showing a semiconductor chip stack package according to another embodiment of the present invention.

FIG. 7 is a cross-sectional view showing a semiconductor chip stack package according to the third embodiment of the present invention.

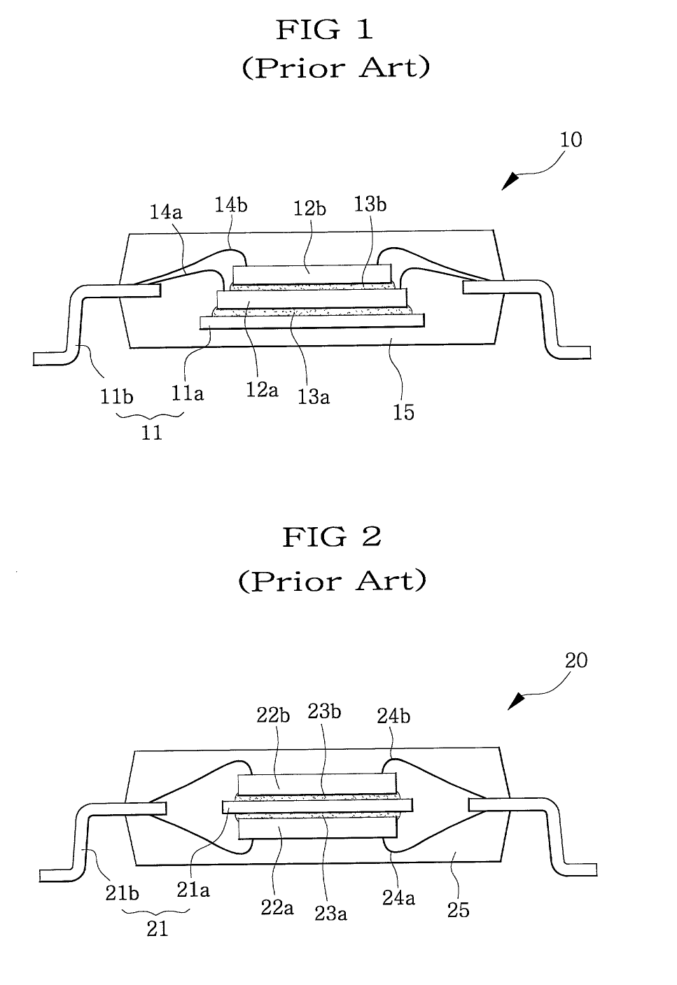

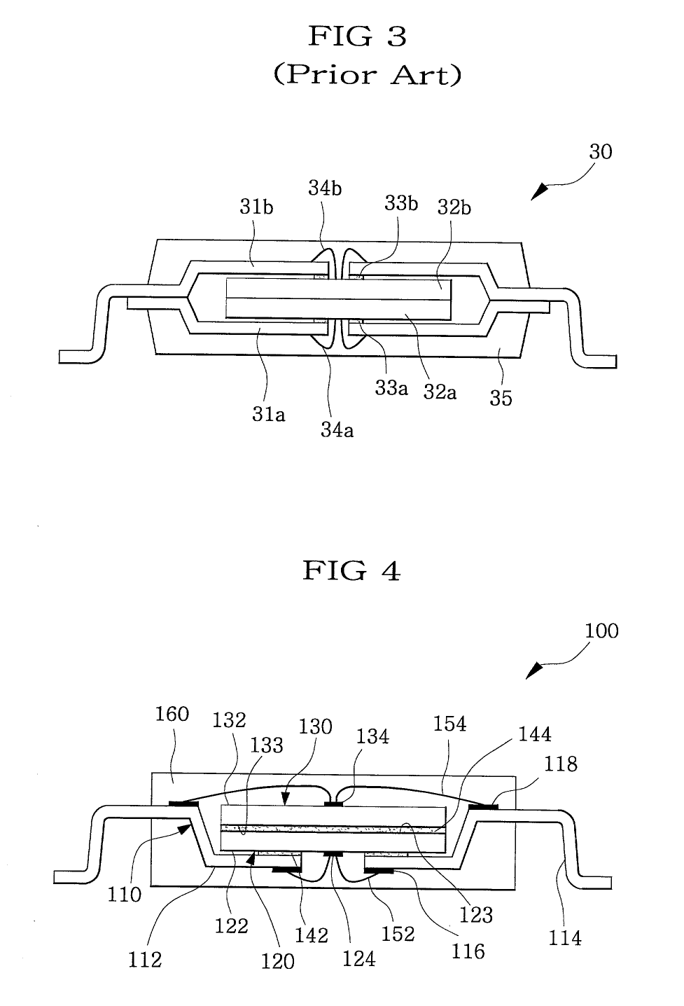

### DETAILED DESCRIPTION OF THE INVENTION

The present invention will now be described more fully hereinafter with reference to accompanying drawings, as compared with the prior art. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, like numbers refer to like elements throughout.

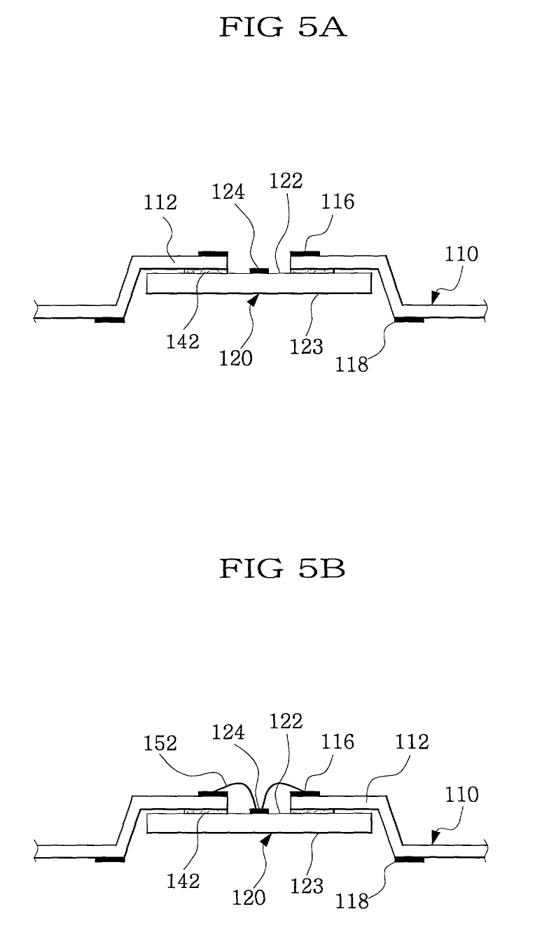

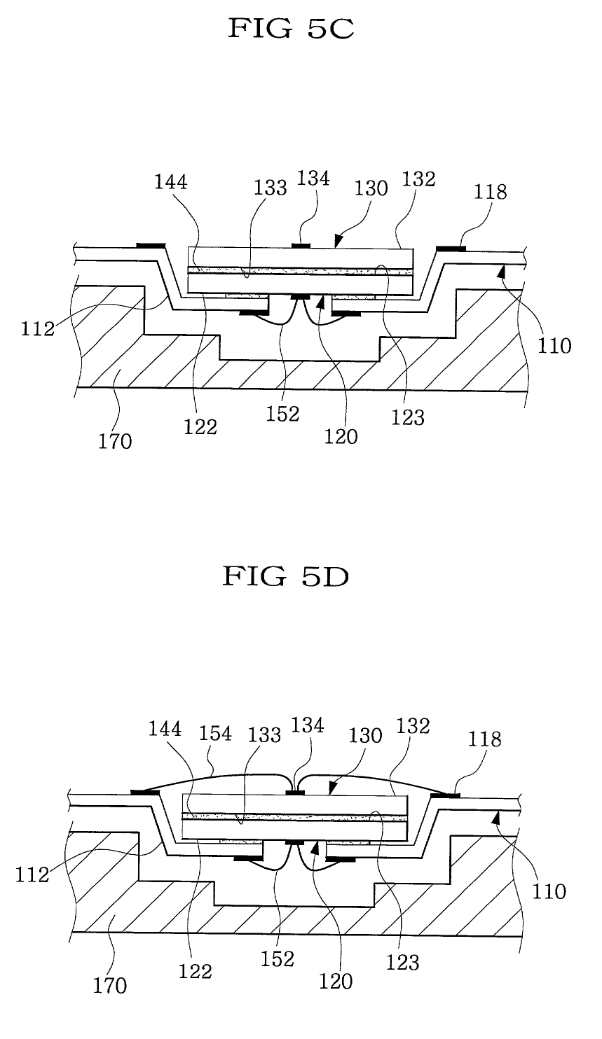

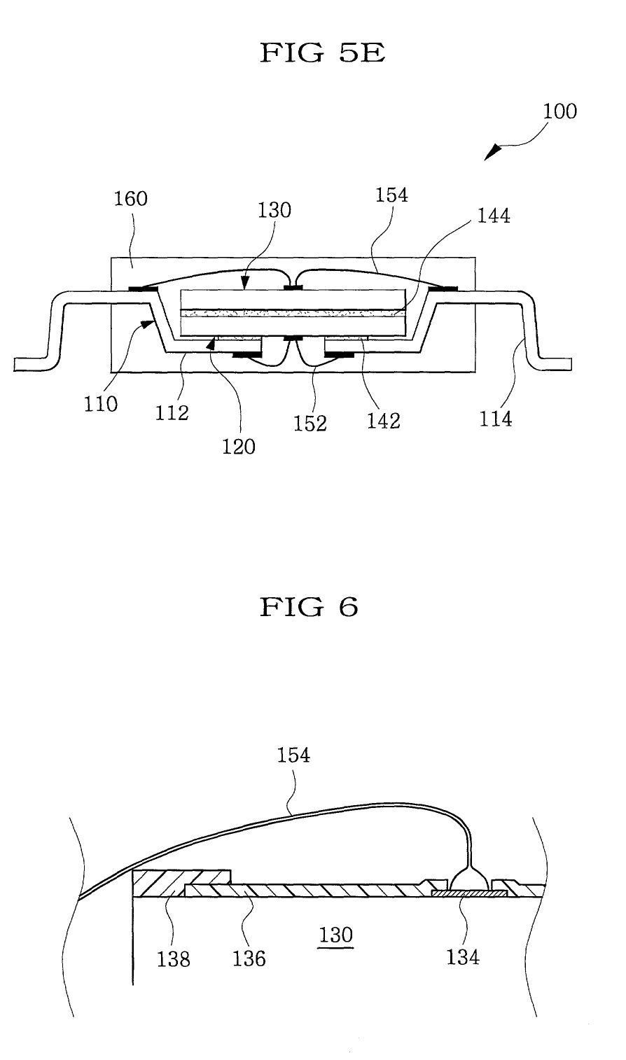

FIG. 4 shows a semiconductor chip stack package 100 according to one embodiment of the present invention. FIGS. 5A to 5E illustrate a method for fabricating the semiconductor chip stack package shown in FIG. 4.

As shown, the stack package 100 employs a single lead-on-chip (LOC) lead frame 110 to accommodate identical type first and second semiconductor chips 120, 130. In particular, the lead frame 110 is attached only to an active surface 122 of the first chip 120, but not attached to an active surface 132 of the second chip 130. The second chip 130 is attached to the first chip 120 with an adhesive 144.

The first and second chips 120, 130 are center pad type chips in which a multiplicity of electrode pads 124, 134 are formed in the central portions of the respective active surfaces 122, 132. The LOC lead frame 110 has a large number of leads disposed over the first chip 120 and arranged near both sides of the electrode pads 124 of the first chip 120. Each of the leads is divided into an inner lead 112 contained in a package mold body 160 and an outer lead 114 projecting out of the package mold body 160.

As clearly depicted in FIG. 4, the inner lead 112 and the outer lead 114 are both bent twice in a vertical structure of the lead frame 110. The inner lead 112 is again divided into three portions. A first portion of the inner lead 112 is arranged over and attached to the active surface 122 of the first chip 120. A second portion extends from the first portion to the active surface 132 of the second chip 130, and a third portion extends from the second portion to the outer lead 114 and is substantially level with the active surface 132 of the second chip 130. On the other hand, the outer lead 114 can have various shapes depending upon the kind of the packages. In addition, the lead frame 110 can be variously designed in a horizontal structure depending on the kind of the chips, the arrangement of the electrode pads, and so forth. Such horizontal structure of the lead frame 100 is also well known in the art and therefore not illustrated in the drawings.

The above-described chip stack package 100 is fabricated as described below. The following explanation for the fabrication of the chip stack package 100 will clarify the structure thereof as well. As shown in FIG. 5A, the first semiconductor chip 120 is attached to the LOC lead frame 110. The lead frame 110 has the inner leads 112 bent twice. The bent portion of the inner leads 112 overlies on the active surface 122 of the first chip 120 and attached thereto by an adhesive tape 142 or other suitable adhesives. The electrode pads 124 acting as electrical connection terminals are interposed between two rows of the inner leads 112. As shown in FIG. 5B, the electrode pads 124 are then electrically connected to the corresponding inner leads 112 by bonding wires 152. Wire-bonded portions of the inner leads 112 are pre-plated with a metal 116 for enhancing wire bondability.

After the electrical connection of the first chip 120, the lead frame 110 is turned over and then placed onto a heater block 170 as shown in FIG. 5C. Thereafter, the second chip 130 is attached to the first chip 120 so that both rear surfaces 123, 133 of the first and second chips 120, 130 are joined to each other by the adhesive 144.

Next, as shown in FIG. 5D, a bonding wire 154 electrically connects each of the electrode pads 134 on the second chip 130 to a plated layer 118 of a corresponding one of the inner leads 112.

The chips 120, 130, the bonding wires 152, 154, and the inner leads 112 are then encapsulated with a mold resin in the package mold body 160 as shown in FIG. 5E.

Next, the outer leads 114 projecting out of the package mold body 160 are formed into an appropriate shape. These processes of forming the package mold body 160 and the outer leads 114 can be performed by well-known techniques for general package manufacturing.

The semiconductor chips 120, 130 are preferably memory integrated circuit devices such as synchronous dynamic random access memory (SDRAM), flash memory, and other kinds of memory devices. When two memory devices 120, 130 are electrically connected to the single lead frame 110, specific electrode pads of the respective memory devices are connected in common to a common lead. For example, an address signal pin, a data input/output signal pin, or a power supply pin is connected in common to the corresponding common lead.

On the other hand, an electrode pad acting as a control signal pin in each memory device is separately connected to different leads so as to select the specific memory device during operation. Therefore, two memory devices can act as a single device and thereby memory density can be doubled. For instance, two SDRAM devices each having a memory density of 128 MB can constitute a single package having a total memory density of 256 MB.

The lead frame 110 is preferably made of copper or iron alloy and manufactured by etching or stamping. The plated layers 116, 118 of the inner leads 112 are formed with silver or nickel to enhance wire bondability as discussed above. The adhesive tape 142 such as a polyimide tape is stuck on the inner leads 112 before the first chip 120 is attached thereto. Then the lead frame 110 is formed into a twice-bent form.

While the second chip 130 is attached and electrically connected, the first chip 120 facing downwardly is disposed on the heater block 170 to protect the bonding wires 152 connected to the first chip 120 from being damaged. If necessary, the heater block 170 may be coated with a non-conductive material. The heater block 170 has a top contour resembling the shape of lead frame 110 to stably support the lead frame 110, and further, has a deeper central portion to avoid contact with the bonding wires 152.

Electrical connections between the second chip 130 and the lead frame 110 require a long bonding wire 154 that may cause a short circuit with edges of the active surface 132 of the second chip 130. To prevent such a short circuit, the top edges of the second chip 132 may be preferably coated with an insulating layer, as illustrated in FIG. 6.

As shown in FIG. 6, the semiconductor chip 130 has the electrode pad 134 formed on the active surface thereof. The active surface except the electrode pad 134 and the edge thereof is coated with a passivation layer 136 formed of nitride and/or polyimide. When the long bonding wire 154 is hanging down and touching silicon exposed at the edge of the chip 130, an undesirable short circuit may result. This can be prevented by an insulating layer 138 formed on the edge of the chip 130 with a non-conductive material such as epoxy or polyimide. A related technique has been described in detail in another U.S. patent application Ser. No. 09/483,252 by the same applicant as the present application.

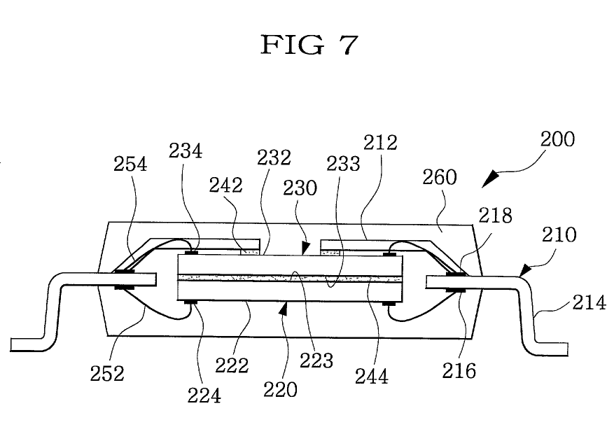

Another semiconductor chip stack package 200 according to the third embodiment of the present invention is illustrated in FIG. 7. Unlike the chip stack packages described above, this chip stack package 200 uses edge pad (peripheral pad) type chips 220, 230, in which electrode pads 224, 234 are formed along peripheral portions of the respective active surfaces 222, 232. In addition, the chip stack package 200 uses an uncommon lead frame 210 having a tie bar 212, namely, a tie bar on chip (TOC) lead frame. The tie bar 212 is not electrically connected to the chips 220, 230, but only attached thereto with an adhesive tape 242 or other suitable adhesives.

When the first chip 230 is attached to the tie bar 242 by the adhesive tape 242, the electrode pads 234 on the first chip 230 are located along both peripheral portions of the active surface 232 excluding a portion where the tie bar 242 passes over. The electrode pads 234 of the first chip 230 are electrically connected to plated layers 218 formed on leads 214 by bonding wires 254.

A rear surface 223 of the second chip 220 is attached to a rear surface 233 of the first chip 230 by an adhesive 224. The electrode pads 224 on the second chip 220 are electrically connected to plated layers 216 formed under the leads 216 by bonding wires 252. A package mold body 260 is formed with a mold resin, and then outer portions of the leads 214 are formed into a suitable form.

As explained hereinbefore, the semiconductor chip stack package according to the present invention can increase in memory density by stacking same-type chips in a single package form. In particular, since the semiconductor chip stack package of the present invention employs a single lead frame, reliability problems in the prior art due to use of two lead frames do not occur. Furthermore, an additional process such as a joining of the lead frames is not required for the semiconductor chip stack package of the present invention. Moreover, since it is possible to use existing fabrication processes and equipment used for a general semiconductor chip package, manufacturing costs are reduced and mass production can be realized. Moreover, a semiconductor chip stack package according to the present invention can effectively adopt center pad-type chips by preventing degradation in reliability due to use of long bonding wires.

In the drawings and specification, there have been disclosed typical preferred embodiments of the invention and, although specific terms are employed, they are used in a generic and descriptive sense only and not for purposes of limitation of the scope of the invention being set forth in the following claims.

What is claimed is:

1. A semiconductor chip stack package comprising:
a first semiconductor chip having a first active surface on which a plurality of first electrode pads are formed and a first rear surface opposite to the first active surface;
a second semiconductor chip having a second active surface on which a plurality of second electrode pads are formed and a second rear surface opposite to the second active surface, the second rear surface facing the first rear surface of said first semiconductor chip;
a single lead frame having a plurality of leads disposed over the first active surface, the plurality of leads being attached to the first active surface; and
each of the first and second electrode pads being electrically connected to a corresponding one of the plurality of leads of the single lead frame.

2. The semiconductor chip stack package of claim 1, wherein the plurality of leads each comprise an outer lead and an inner lead, the inner lead including: first, second and third portions, the third portions, the second portion connecting the first and third portions,
wherein the first portion is attached to the first active surface, and
wherein the third portion is substantially level with the second active surface.

3. The semiconductor chip stack package of claim 1, further comprising:
a package mold body encapsulating said first and second semiconductor chips, and inner portions of the respective leads of said lead frame.

4. The semiconductor chip stack package of claim 1, wherein the first and second electrode pads are formed in central portions of the first and second active surfaces of said first and second semiconductor chips.

5. The semiconductor chip stack package of claim 1, wherein said second semiconductor chip further has an insulating layer formed on edge portions of the second active surface.

6. The semiconductor chip stack package of claim 1, wherein the first and second electrode pads are formed along peripheral portions of the first and second active surfaces of said first and second semiconductor chips.

7. The semiconductor chip stack package of claim 1, wherein said first and second semiconductor chips are substantially identical.

8. The semiconductor chip stack package of claim 7, wherein said first and second semiconductor chips include a memory device.

9. The semiconductor chip stack package of claim 1, wherein a predetermined one of the first electrode pads and a predetermined one of the second electrode pads are connected in common to a corresponding one of the leads of the single lead frame.

10. The semiconductor chip package of claim 9, wherein the electrical connection is formed by bonding wires.

11. A semiconductor chip stack package comprising:
a first semiconductor chip including a first active surface having a plurality of first electrode pads formed along a central portion thereof and a first rear surface opposite to the first active surface;
a second semiconductor chip including a second active surface having a plurality of second electrode pads formed along a central portion thereof and a second rear surface opposite to the second active surface, the second rear surface facing the first rear surface of said first semiconductor chip;
a package mold body encapsulating said first and second semiconductor chips;
a single lead frame including a plurality of leads arranged near both sides of the first electrode pads, each lead having an inner lead embedded in said package mold body and an outer lead projecting out of said package mold body, and the inner leads being attached to the first active surface; and
each of the first and second electrode pads being electrically connected to a corresponding one of the inner leads.

12. The semiconductor chip stack package of claim 11, wherein each of the inner leads has a first portion attached to the first active surface, a second portion extended from the first portion to the second active surface, and a third portion extended from the second portion to the outer lead, the third portion being substantially level with the second active surface.

13. The semiconductor chip stack package of claim 11, wherein said first and second semiconductor chips include a memory device.

14. The semiconductor chip stack package of claim 11, wherein said second semiconductor chip further has an insulating layer formed on edge portions of the second active surface.

15. The semiconductor chip stack package of claim 11, wherein said first and second semiconductor chips are identical.

16. A method for fabricating a semiconductor chip stack package, comprising:
providing a single lead frame, a first semiconductor chip, and a second semiconductor chip, wherein the single lead frame has a plurality of leads, wherein the first semiconductor chip has a first active surface on which a plurality of first electrode pads are formed and a first rear surface opposite to the first active surface, and wherein the second semiconductor chip has a second active surface on which a plurality of second electrode pads are formed and a second rear surface opposite to the second active surface;
attaching the first semiconductor chip to the single lead frame so that the leads are disposed over and attached to the first active surface;
electrically connecting the first electrode pads of the first semiconductor chip to a corresponding one of the leads of the single lead frame;
attaching the second semiconductor chip to the first semiconductor chip so that the second rear surface faces the first rear surface; and
electrically connecting the second electrode pads of the second semiconductor chip to a corresponding one of the leads of the single lead frame.

17. The method of claim 16, further comprising:
forming a package mold body so that the first and second semiconductor chips, and inner leads of the single lead frame are encapsulated therein.

18. The method of claim 16, wherein electrically connecting the first and second electrode pads to the corresponding one of the leads of single the lead frame comprises using bonding wires.
